(19) United States
(12) Patent Application Publication
(10) Pub. No.: US 2021/0343759 A1
(43) Pub. Date: Nov. 4, 2021

(54) ARRAY SUBSTRATE AND METHOD FOR MANUFACTURING THE SAME

(71) Applicant: WUHANCHINASTAROPTOELECTRONICSSEMICONDUCTORDISPLAYTECHNOLOGYCO,.LTD, Wuhan (CN)

(72) Inventor: Chao Li, Wuhan (CN)

(73) Assignee: WUHAN CHINA STAR OPTOELECTRONICS SEMICONDUCTOR DISPLAY TECHNOLOGY CO., LTD., Wuhan (CN)

(21) Appl. No.: 16/337,530

(22) PCT Filed: Aug. 23, 2018
(86) PCT No.: PCT/CN2018/101835

§ 371 Date: Mar. 28, 2019

(30) Foreign Application Priority Data
May 3, 2018 (CN) 201810412387.X

(51) Int. Cl. H01L 27/12; H01L 21/28

(52) U.S. Cl. CPC H01L 27/1259; H01L 21/28247; H01L 21/02071; H01L 27/124; H01L 27/1255

(57) ABSTRACT

The present invention provides an array substrate and a method for manufacturing the array substrate. The method includes: providing a substrate and forming a buffer layer, a poly-silicon layer and a first gate insulating layer sequentially on the substrate; and forming a first gate metal layer on the first gate insulating layer, forming a first photoresist stickiness maintaining metal film on the first gate metal layer, forming a patterned gate electrode and a first patterned photoresist stickiness maintaining metal on a surface of the patterned gate electrode by a first developing process.

### CROSS REFERENCE TO RELATED APPLICATION

This application claims the priority of International Application No. PCT/CN2018/101835, filed on 2018 Aug. 23, which claims priority to Chinese Application No. 201810412387.X, filed on 2018 May 3. The entire disclosures of each of the above applications are incorporated herein by reference.

### BACKGROUND OF THE INVENTION

### Field of Invention

The present invention relates to a display manufacturing technology field, and particularly to an array substrate and a method for manufacturing the array substrate.

### Description of Prior Art

In an active matrix/organic light emitting diode (AMOLED) display producing process, a layer of plastic film (the currently material is polyimide) is first coated on a glass substrate as a base substrate for an array substrate process, and then an array substrate preparation is applied on the base substrate, and a thin film transistor (TFT) array substrate is formed by 11 mask processes. A part of a structure is shown in FIG. 1, in a preparation for manufacturing a Gate(gate), a first gate insulating layer 102 is formed after a former preparation (a poly-silicon layer 101), a first gate metal film (metal material is made of Mo, molybdenum) is formed on the first gate insulating layer 102, and then a first photo lithography process is applied to the first gate metal film, a patterned gate 103 is formed by a first etching process, a layer of a second gate insulating layer 104 is formed after the patterned gate 103 formed, a second gate metal film (metal material is made of Mo, molybdenum) is formed, a second photo lithography process is applied, a gate capacitor 106 is formed by a second etching process, and then a dielectric layer is formed on the gate capacitor 106.

In the photo lithography processes for forming the first gate metal film and the second gate metal film, because metal Mo is easily oxidized, and the organic solvents exist in the clean chamber environment and easily adhere on a surface of the metal Mo to decrease a stickiness of a photoresist, and to make the gate line to be broken due to the non-stickiness of the photoresist after the photo lithography exposing process, thereby to affect a conductivity of a display device.

Therefore, it is necessary to provide an array substrate and a manufacturing method to solve the problems existing in the prior art.

### SUMMARY OF THE INVENTION

The disclosure of the present application provides an array substrate and a method for manufacturing the array substrate to protect a metal Mo used for forming a gate and a gate capacitor not to be corroded and oxidized in the manufacturing environment, and to ensure a stickiness of a photoresist to make the gate line not to be broken during a photo lithography process.

For the above-mentioned objective, the present disclosure employs the following technical schemes.

The disclosure of application provides a method for manufacturing an array substrate, the method includes:

a step S1 of providing a substrate and forming a buffer layer, a poly-silicon layer and a first gate insulating layer sequentially on the substrate; and

a step S2 of forming a first gate metal layer on the first gate insulating layer, forming a first photoresist stickiness maintaining metal film on the first gate metal layer, forming a patterned gate electrode and a first patterned photoresist stickiness maintaining metal on a surface of the patterned gate electrode by a first developing process; wherein the first patterned photoresist stickiness maintaining metal and the gate electrode are manufactured by a same mask process.

In one exemplary embodiment of the disclosure, the method further includes:

a step S3 of forming a second gate insulating layer, a second gate metal layer and a second photoresist stickiness maintaining metal film sequentially on the first patterned photoresist stickiness maintaining metal, forming a patterned gate capacitor and a second patterned photoresist stickiness maintaining metal on the patterned gate capacitor by a second developing process; and wherein the second patterned photoresist stickiness maintaining metal and the patterned gate capacitor are manufactured by a same mask process.

In one exemplary embodiment of the disclosure, the method further includes:

a step S4 of forming a dielectric layer on the second patterned photoresist stickiness maintaining metal, defining via holes corresponding to a source region and a drain region of the poly-silicon layer and penetrating the dielectric layer, the second gate insulating layer and the first gate insulating layer by a patterning process; and

a step S5 of forming a source and drain metal layer on the dielectric layer, forming a source electrode electrically connecting the source region and a drain electrode electrically connecting the drain region by a patterning process.

In one exemplary embodiment of the disclosure, the first gate metal layer and the second gate metal layer are made of molybdenum.

In one exemplary embodiment of the disclosure, each of a thickness of the first gate metal layer and a thickness of the second gate metal layer is about 2500 angstroms (Å).

In one exemplary embodiment of the disclosure, the first photoresist stickiness maintaining metal film and the second photoresist stickiness maintaining metal film are made of titanium (Ti).

In one exemplary embodiment of the disclosure, each of a thickness of the first photoresist stickiness maintaining metal film and a thickness of the second photoresist stickiness maintaining metal film is about 500 angstroms (Å).

In one exemplary embodiment of the disclosure, a manufacturing method of the first photoresist stickiness maintaining metal film and the second photoresist stickiness maintaining metal film includes a coating method by a vacuum sputtering coating machine.

The application provides an array substrate, including: a substrate; a buffer layer formed on the substrate; a poly-silicon layer formed on the buffer layer; a first gate insulating layer formed on the poly-silicon layer; a gate electrode corresponding to the poly-silicon layer and formed on the first gate insulating layer; and a first photoresist stickiness maintaining metal film formed on a surface of the gate electrode; wherein a projection area of the first photoresist stickiness maintaining metal film on the substrate overlaps with a projection area of the gate electrode on the substrate.

In one exemplary embodiment of the disclosure, the array substrate further includes: a second gate insulating layer formed on the first photoresist stickiness maintaining metal film; a gate capacitor corresponding to the gate electrode and formed on the second gate insulating layer; and a second photoresist stickiness maintaining metal film formed on a surface of the gate capacitor; wherein a projection area of the second photoresist stickiness maintaining metal film on the substrate overlaps with a projection of the gate capacitor on the substrate.

The beneficial effect of this invention is: in the array substrate and the manufacturing method, a photoresist stickiness maintaining metal film (such as Ti) is formed on metal Mo of a gate and a gate capacitor to protect the metal Mo not to be oxidized, and the photoresist stickiness maintaining metal film has a good performance of corrosion resistance and is not easily polluted by organic solvents in the manufacturing environment to maintain a stickiness of the photo lithograthy photoresist and to prevent from decreasing a stickiness of the photoresist with an easy process and a low cost, a gate line broken problem due to the stickiness of the gate photoresist decreasing is solved without increasing masks.

### BRIEF DESCRIPTION OF THE DRAWINGS

In order to describe clearly the embodiment in the present disclosure or the prior art, the following will introduce the drawings for the embodiment shortly. Obviously, the following description is only a few embodiments, for the common technical personnel in the field it is easy to acquire some other drawings without creative work.

FIG. 1 is a structure diagram of an array substrate in the prior art.

FIG. 2 is a flow chart of a method for manufacturing an array substrate according to one exemplary embodiment of the present disclosure.

FIGS. 3A-3L are structure diagrams of an array substrate during manufacturing flows according to one exemplary embodiment of the present disclosure.

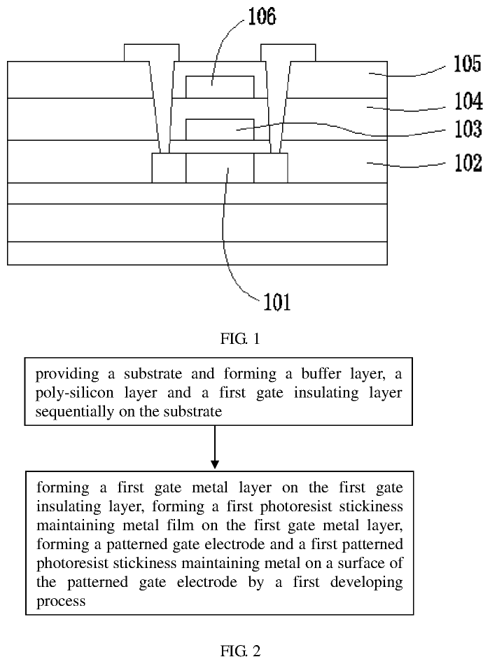

### DETAILED DESCRIPTION OF THE PREFERRED EMBODIMENTS

The description of following embodiment, with reference to the accompanying drawings, is used to exemplify specific embodiments which may be carried out in the present disclosure. Directional terms mentioned in the present disclosure, such as “top”, “bottom”, “front”, “back”, “left”, “right”, “inside”, “outside”, “side”, etc., are only used with reference to the orientation of the accompanying drawings. Therefore, the used directional terms are intended to illustrate, but not to limit, the present disclosure. In the drawings, the components having similar structures are denoted by same numerals.

The disclosure solves technical problems that metal Mo is easily oxidized in a gate photo lithography process, and the organic solvents exist in the manufacturing environment and easily adhere on a surface of the metal Mo to decrease a stickiness of a photoresist, and to make the gate line to be broken due to the non-stickiness of the photoresist after the photo lithography exposing process.

Referring to FIG. 2, FIG. 2 is a flow chart of a method for manufacturing an array substrate according to one exemplary embodiment of the present disclosure. The method includes:

Step S1, a substrate is provided, a buffer layer, a poly-silicon layer and a first gate insulating layer are sequentially formed on the substrate.

Referring to 3A, a base substrate 301 is provided. The base substrate comprises a display region and a non-display region. A buffer layer 302 is formed on the base substrate 301. A patterned poly-silicon layer 303 is formed on the buffer layer corresponding to the display region, and the poly-silicon layer 303 comprises a source region and a drain region placed two ends of the poly-silicon layer 303, a cleaning device 304 is applied to clean a surface of the poly-silicon layer 303.

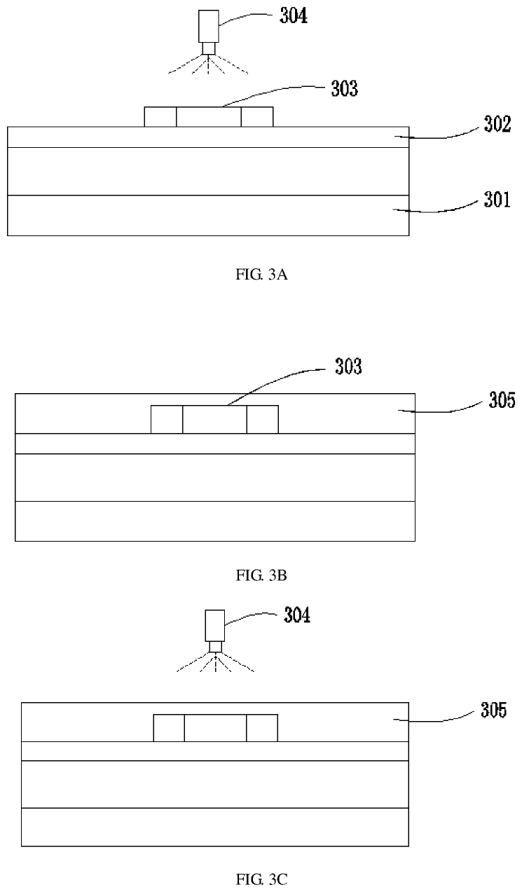

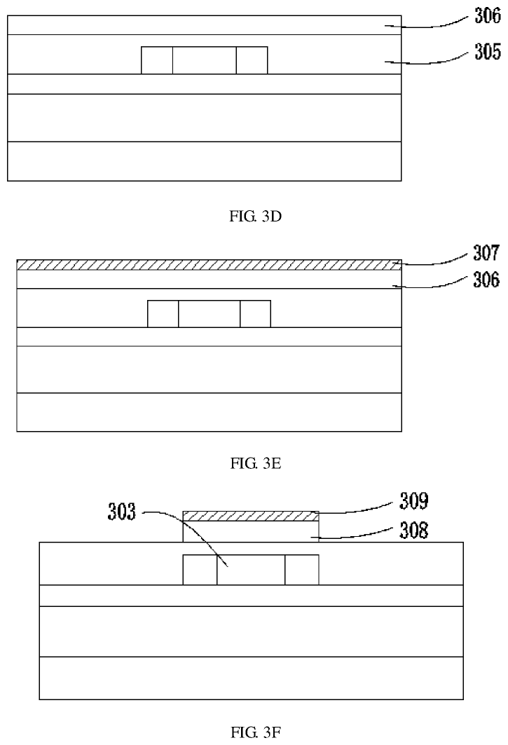

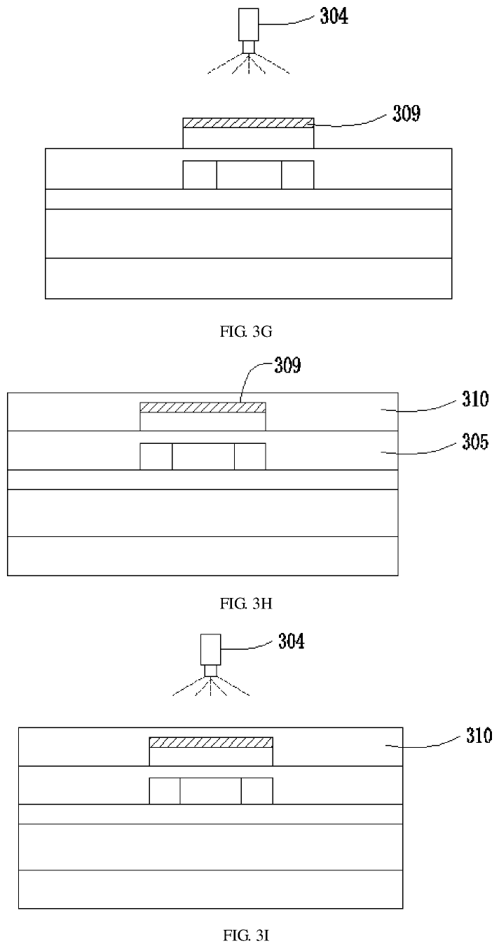

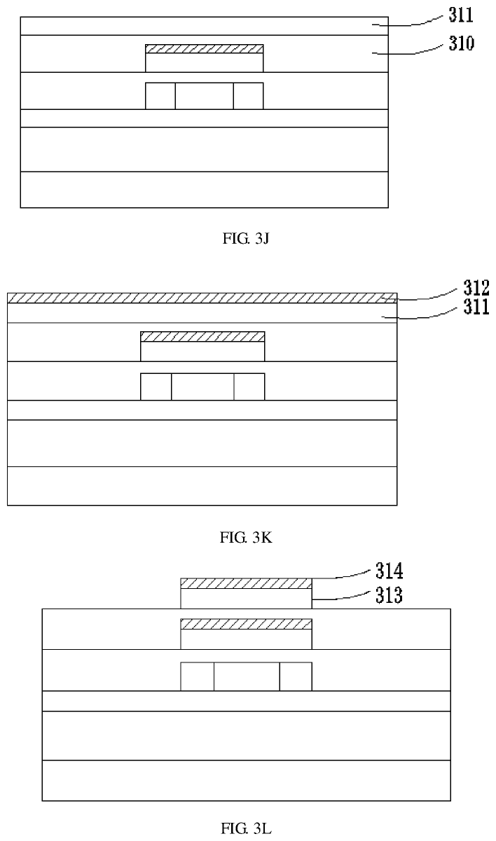

Referring to FIG. 3B, a first gate insulating layer 305 is formed on the surface of the poly-silicon layer 303. Material of the first gate insulating layer 305 is non-metallic material, such as SiO₂. A thickness of the first gate insulating layer 305 is about 1300 angstroms (Å). The cleaning device 304 is applied to clean a surface of the first gate insulating layer 305, shown in FIG. 3C.

Step S2, a first gate metal layer is formed on the first gate insulating layer, a first photoresist stickiness maintaining metal film is formed on the first gate metal layer, a patterned gate electrode and a first patterned photoresist stickiness maintaining metal on a surface of the patterned gate electrode are formed by a first developing process.

Referring to FIG. 3D, a layer of a first gate metal layer 306 is formed on the surface of the first gate insulating layer 305. Preferably, the first gate metal layer 306 is made of molybdenum (Mo). Preferably, a thickness of the first gate metal layer 306 is about 2500 angstroms (Å). The metal Mo is easily oxidized in air and is easily polluted by organic solvents in the manufacturing environment to cause undesirable phenomenon, such as break lines, but it has a good conductivity, and if it is used in a display device by solving the above problems to ensure a good performance of the display device.

Referring to FIG. 3E, a layer of a first photoresist stickiness maintaining metal film 307 is formed on the first gate metal layer 306. A manufacturing method of the first photoresist stickiness maintaining metal film 307 can be a coating method by a vacuum sputtering coating machine. The first photoresist stickiness maintaining metal film 307 has a good inoxidizability and a good corrosion resistance to protect the metal Mo not to be oxidized, and to protect the metal Mo not easily polluted by organic solvents in the manufacturing environment to prevent from decreasing a stickiness of the photoresist. Preferably, a thickness of the first photoresist stickiness maintaining metal film 307 is about 500 angstroms (Å). It is found that a source and drain (SD) layers are exposed by a photo lithography process in a same clean chamber environment, a problem of break lines caused by a decreasing stickiness of the photoresist does not exist, the SD layer film is made of Ti—Al—Ti or Ti with a good corrosion resistance and not easily to be oxidized, and the metal Ti is not easily affected by the organic solvents, and not generates a problem of break lines caused by a decreasing stickiness of the photoresist. Therefore, the material used for the first photoresist stickiness maintaining metal film 307 is same as the metal Ti or similar metals of Ti. Preferably, the first photoresist stickiness maintaining metal film 307 is made of Ti.

FIG. 3F, a layer of a photoresist is formed on a surface of the first photoresist stickiness maintaining metal film 307 and a first photo lithography process is applied. A patterned gate electrode 308 and a first patterned photoresist stickiness maintaining metal 309 formed on a surface of the gate electrode 308 are manufactured by a same mask process and by a developing process. The gate electrode 308 and the first patterned photoresist stickiness maintaining metal 309 are on the position corresponding to the poly-silicon layer 303. Then the cleaning device 304 is applied to clean a surface of the first patterned photoresist stickiness maintaining metal 309, shown in FIG. 3G.

Step S3, a second gate insulating layer, a second gate metal layer and a second photoresist stickiness maintaining metal film are sequentially formed on the first patterned photoresist stickiness maintaining metal, a patterned gate capacitor and a second patterned photoresist stickiness maintaining metal on the patterned gate capacitor are formed by a second developing process.

Referring to 3H, a layer of second gate insulating layer 310 is formed on the surface of the first patterned photoresist stickiness maintaining metal 309 and the surface of the first gate insulating layer 305. In at least one embodiment, material of the second gate insulating layer 310 can be a non-metallic material, such as SiNₓ. In at least one embodiment, a thickness of the second gate insulating layer 310 is about 1200 angstroms (Å). Then the cleaning device 304 is applied to clean a surface of the second gate insulating layer 310, shown in FIG. 31.

Referring to FIG. 3J, a layer of a second gate metal layer 311 is formed on the surface of the second gate insulating layer 310. Preferably, material of the second gate metal layer 311 can be metal, such as Mo. Preferably, a thickness of the second gate metal layer 311 is about 2500 angstroms (Å).

Referring to FIG. 3K, a layer of second photoresist stickiness maintaining metal film 312 is formed on the surface of the second gate metal layer 311. A manufacturing method of the second photoresist stickiness maintaining metal film 312 can be a coating method by a vacuum sputtering coating machine. Materials of the second photoresist stickiness maintaining metal film 312 and the first photoresist stickiness maintaining metal film 307 are same, such as metal Ti preferably. Preferably, a thickness of the second photoresist stickiness maintaining metal film 312 is about 500 angstroms (Å).

Referring to FIG. 3L, a layer of a photoresist is formed on the surface of the second photoresist stickiness maintaining metal film 312 and a second photo lithography process is applied. A patterned gate capacitor 313 and a second patterned photoresist stickiness maintaining metal 314 on the patterned gate capacitor gate capacitor 313 are formed by a same mask process and by one time developing process. The patterned gate capacitor 313 and the second patterned photoresist stickiness maintaining metal 314 is placed corresponding to a position of the poly-silicon layer 303.

In addition, the method for manufacturing the array substrate further includes:

Step S4, a dielectric layer is formed on the second patterned photoresist stickiness maintaining metal, via holes are defined corresponding to a source region and a drain region of the poly-silicon layer and penetrating the dielectric layer, the second gate insulating layer and the first gate insulating layer by a patterning process.

Step S5, a source and drain metal layer is formed on the dielectric layer, a source electrode electrically connecting the source region and a drain electrode electrically connecting the drain region are formed by a patterning process

It is understandably that materials of the first photoresist stickiness maintaining metal film and the second photoresist stickiness maintaining metal film are not limited in to metal Ti, and can be other metal with a good inoxidizability, a good corrosion resistance, and not affecting the stickiness of the photoresist.

The disclosure also provides an array substrate manufactured by the above method, the array substrate is used to manufacture a flexible AMOLED display panel or liquid crystal display panel. The array substrate includes: a substrate and a buffer layer, a poly-silicon layer, a first gate insulating layer formed sequentially formed on the substrate; a gate electrode corresponding to the poly-silicon layer and formed on the first gate insulating layer; a first photoresist stickiness maintaining metal film formed on a surface of the gate electrode; a second gate insulating layer formed on the first photoresist stickiness maintaining metal film; a gate capacitor corresponding to the gate electrode and formed on the second gate insulating layer; and a second photoresist stickiness maintaining metal film formed on a surface of the gate capacitor.

A projection area of the first photoresist stickiness maintaining metal film on the substrate overlaps with a projection area of the gate electrode on the substrate. A projection area of the second photoresist stickiness maintaining metal film on the substrate overlaps with a projection of the gate capacitor on the substrate.

In the array substrate and the manufacturing method, a photoresist stickiness maintaining metal film (such as Ti) is formed on metal Mo of a gate and a gate capacitor to protect the metal Mo not to be oxidized, and the photoresist stickiness maintaining metal film has a good performance of corrosion resistance and is not easily polluted by organic solvents in the manufacturing environment to maintain a stickiness of the photo lithography photoresist and to prevent from decreasing a stickiness of the photoresist with an easy process and a low cost, a gate line broken problem due to the stickiness of the gate photoresist decreasing is solved without increasing masks.

As is understood by persons skilled in the art, the foregoing preferred embodiments of the present disclosure are illustrative rather than limiting of the present disclosure. It is intended that they cover various modifications and that similar arrangements be included in the spirit and scope of the present disclosure, the scope of which should be accorded the broadest interpretation so as to encompass all such modifications and similar structures. cm What is claimed is:

1. A method for manufacturing an array substrate, wherein the method comprises:
a step S1 of providing a substrate and forming a buffer layer, a poly-silicon layer and a first gate insulating layer sequentially on the substrate; and
a step S2 of forming a first gate metal layer on the first gate insulating layer, forming a first photoresist stickiness maintaining metal film on the first gate metal layer, forming a patterned gate electrode and a first patterned photoresist stickiness maintaining metal on a surface of the patterned gate electrode by a first developing process;
wherein the first patterned photoresist stickiness maintaining metal and the gate electrode are manufactured by a same mask process.

2. The method of claim 1, wherein the method further comprises:
a step S3 of forming a second gate insulating layer, a second gate metal layer and a second photoresist stickiness maintaining metal film sequentially on the first patterned photoresist stickiness maintaining metal, forming a patterned gate capacitor and a second patterned photoresist stickiness maintaining metal on the patterned gate capacitor by a second developing process; and
wherein the second patterned photoresist stickiness maintaining metal and the patterned gate capacitor are manufactured by a same mask process.

3. The method of claim 1, wherein the method further comprises:
a step S4 of forming a dielectric layer on the second patterned photoresist stickiness maintaining metal, defining via holes corresponding to a source region and a drain region of the poly-silicon layer and penetrating the dielectric layer, the second gate insulating layer and the first gate insulating layer by a patterning process; and
a step S5 of forming a source and drain metal layer on the dielectric layer, forming a source electrode electrically connecting the source region and a drain electrode electrically connecting the drain region by a patterning process.

4. The method of claim 2, wherein the first gate metal layer and the second gate metal layer are made of molybdenum.

5. The method of claim 2, wherein each of a thickness of the first gate metal layer and a thickness of the second gate metal layer is about 2500 angstroms (Å).

6. The method of claim 2, wherein the first photoresist stickiness maintaining metal film and the second photoresist stickiness maintaining metal film are made of titanium.

7. The method of claim 2, wherein each of a thickness of the first photoresist stickiness maintaining metal film and a thickness of the second photoresist stickiness maintaining metal film is about 500 angstroms (Å).

8. The method of claim 2, wherein a manufacturing method of the first photoresist stickiness maintaining metal film and the second photoresist stickiness maintaining metal film comprises a coating method by a vacuum sputtering coating machine.

9. An array substrate, comprising:
a substrate;
a buffer layer formed on the substrate;
a poly-silicon layer formed on the buffer layer;
a first gate insulating layer formed on the poly-silicon layer;
a gate electrode corresponding to the poly-silicon layer and formed on the first gate insulating layer; and
a first photoresist stickiness maintaining metal film formed on a surface of the gate electrode;
wherein a projection area of the first photoresist stickiness maintaining metal film on the substrate overlaps with a projection area of the gate electrode on the substrate.

10. The array substrate of the claim 9, wherein the array substrate further comprises:
a second gate insulating layer formed on the first photoresist stickiness maintaining metal film;
a gate capacitor corresponding to the gate electrode and formed on the second gate insulating layer; and
a second photoresist stickiness maintaining metal film formed on a surface of the gate capacitor;
wherein a projection area of the second photoresist stickiness maintaining metal film on the substrate overlaps with a projection of the gate capacitor on the substrate.
